(19) United States
(12) Patent Application Publication
(10) Pub. No.: US 2013/0146954 A1
(43) Pub. Date: Jun. 13, 2013

(54) Method Of Memory Array And Structure Form

(71) Applicants: Tzung-Han Lee, Taipei City (TW); Chung-Lin Huang, Taoyuan County (TW); Ron Fu Chu, Taipei City (TW)

(72) Inventors: Tzung-Han Lee, Taipei City (TW); Chung-Lin Huang, Taoyuan County (TW); Ron Fu Chu, Taipei City (TW)

(21) Appl. No.: 13/429,448

(22) Filed: Mar. 26, 2012

(30) Foreign Application Priority Data
Dec. 8, 2011 (TW) 100145254

(51) Int. Cl. H01L 27/088; H01L 21/336

(52) U.S. Cl. 257/296; 438/239; 257/E21.409; 257/E27.06

(57) ABSTRACT

The present invention provides a memory array including a substrate, an isolation region, a plurality of active regions, a plurality of buried bit lines, a plurality of word lines, a plurality of drain regions and a plurality of capacitors. The isolation region and the active regions are disposed in the substrate and the active regions are encompassed and isolated by the isolation region. The buried bit lines are disposed in the substrate and extend in the second direction. The word lines are disposed in the substrate extend in the first direction. The drain regions are disposed in the active region not covered by the word lines. The capacitors are disposed on the substrate and electrically connected to the drain regions.

### BACKGROUND OF THE INVENTION

1. Field of the Invention

The present invention relates to a memory array, and more particularly to a memory array with buried bit lines and a novel array arrangement.

2. Description of the Prior Art

In order to enhance the operating speed of semiconductor devices and to meet the demands of miniaturization, the size of the transistors in semiconductor circuits tends to be reduced. However, as the semiconductor device size shrinks, the channel length of the transistor is reduced as well. Consequently, a phenomenon of short channel effect and the reduction of on current (Ion) impacts the functioning of the transistor. To overcome this problem; one solution is to raise the dopant concentration in the channel region. However, this may increase the leakage current and affect the reliability of the devices.

Another approach to solve the above problems that has been developed recently is to change the transistor with a horizontal channel into the transistor with a vertical channel. For example, the transistor with vertical channel can be formed in a deep trench. This way, the vertical channel transistor can provide high operating speed and the short channel effect can be avoided. However, there are still some problems for forming the vertical channel transistor.

### SUMMARY OF THE INVENTION

The present invention provides a memory array and a method of making the same. The memory array includes vertical channel transistors and buried bit lines so that the integrity of the semiconductor circuits can be enhanced and the operating speed can be improved.

According to one embodiment, the present invention provides a memory array including a substrate, an isolation region, a plurality of active regions, a plurality of buried bit lines, a plurality of word lines, a plurality of drain regions and a plurality of capacitors. The isolation region and the active regions are disposed in the substrate and the active regions are encompassed and isolated by the isolation region. The buried bit lines are disposed in the substrate and extend along the second direction. The word lines are disposed in the substrate and extend along the first direction. The drain regions are disposed in the active region not covered by the word lines. The capacitors are disposed on the substrate and electrically connected to the drain regions.

According to another embodiment, the present invention provides a method of making a memory array. A substrate is provided, and a first direction and a second direction, which are substantially perpendicular to each other, are defined on the substrate. Then, an isolation region is formed in the substrate to define a plurality of active regions encompassed by the isolation region. Subsequently, a plurality of buried bit lines are formed in the substrate and extend along the second direction and a plurality of word lines are formed in the substrate and extend along the first direction. A gate dielectric layer is formed between the substrate and the word line. Then, a drain region is formed in the active region not covered by the word line. Finally, a plurality of capacitors is formed on the substrate, which are electrically connected to each drain region.

The present invention provides a memory array and the manufacturing method thereof. The novel arrangement of the active regions and the isolation region is one salient feature of the present invention. The vertical transistors and the buried bit lines are therefore formed on the substrate according to the arrangement.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 1A, FIG. 1B, FIG. 2 to FIG. 6, FIG. 7, FIG. 7A, FIG. 7B, FIG. 8, FIG. 8A, FIG. 8B, FIG. 9, FIG. 9A, FIG. 9B, FIG. 10, FIG. 10A and FIG. 10B are schematic diagrams of a method of manufacturing the memory array in the present invention.

### DETAILED DESCRIPTION

In order to provide a better understanding of the present invention to those of ordinarily skilled in the art, several preferred embodiments are enumerated with reference to the accompanying drawings, to explain the construction and the desired effects of the present invention.

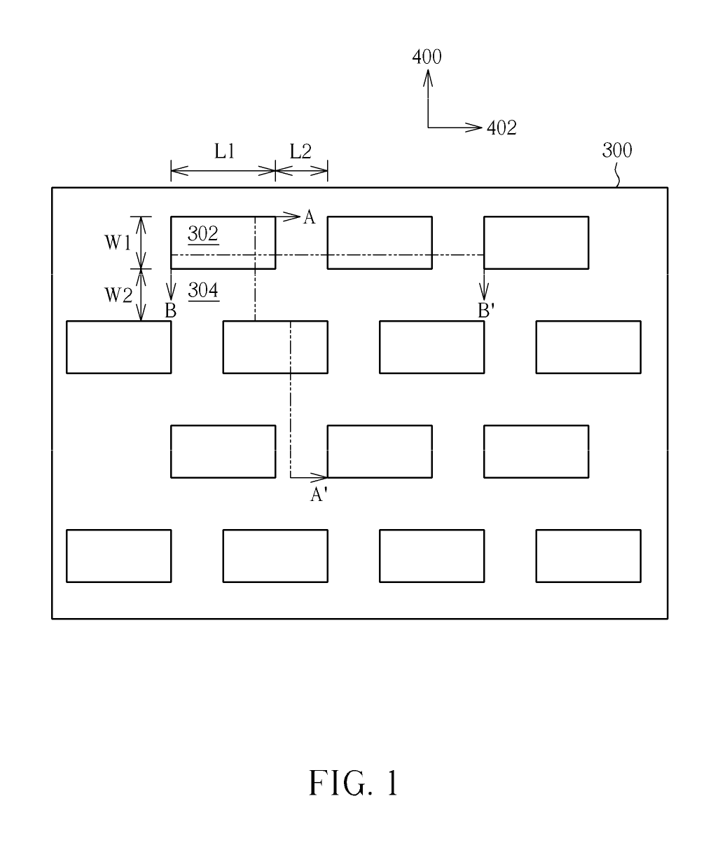

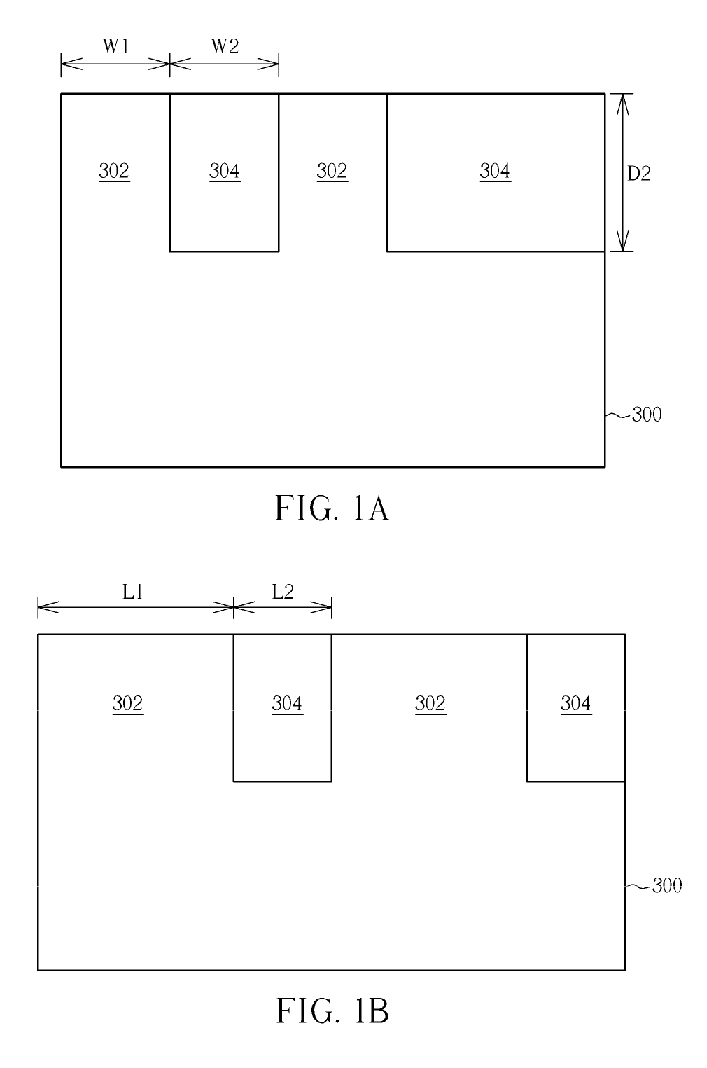

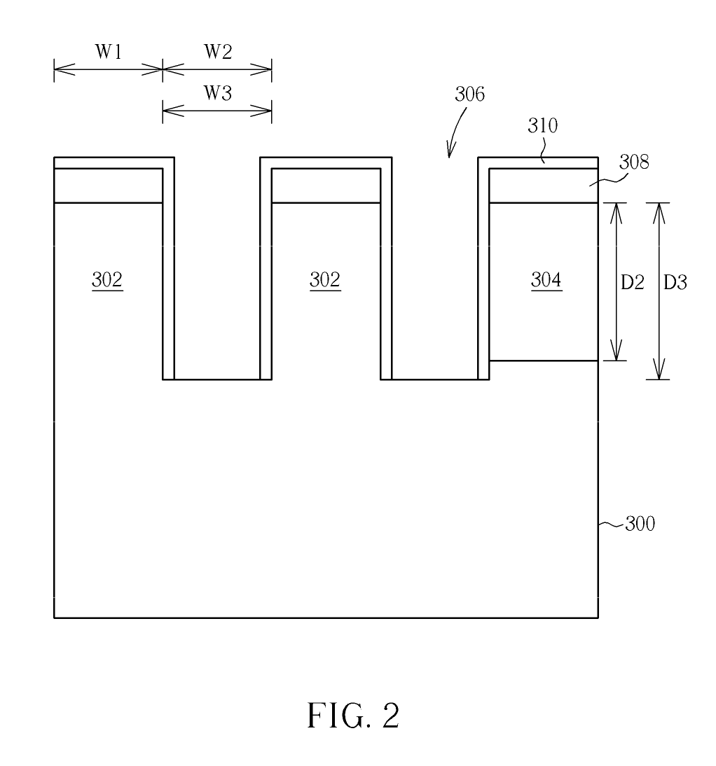

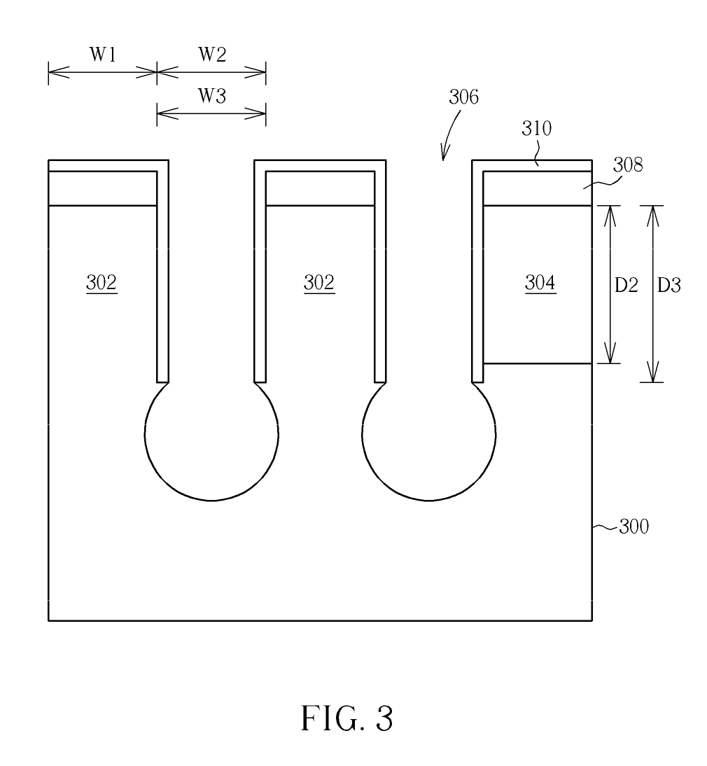

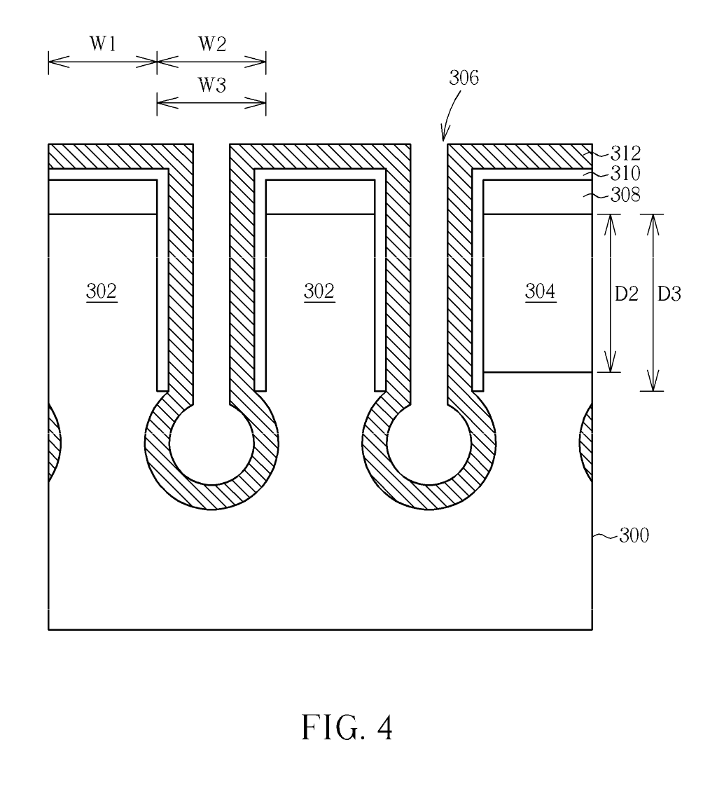

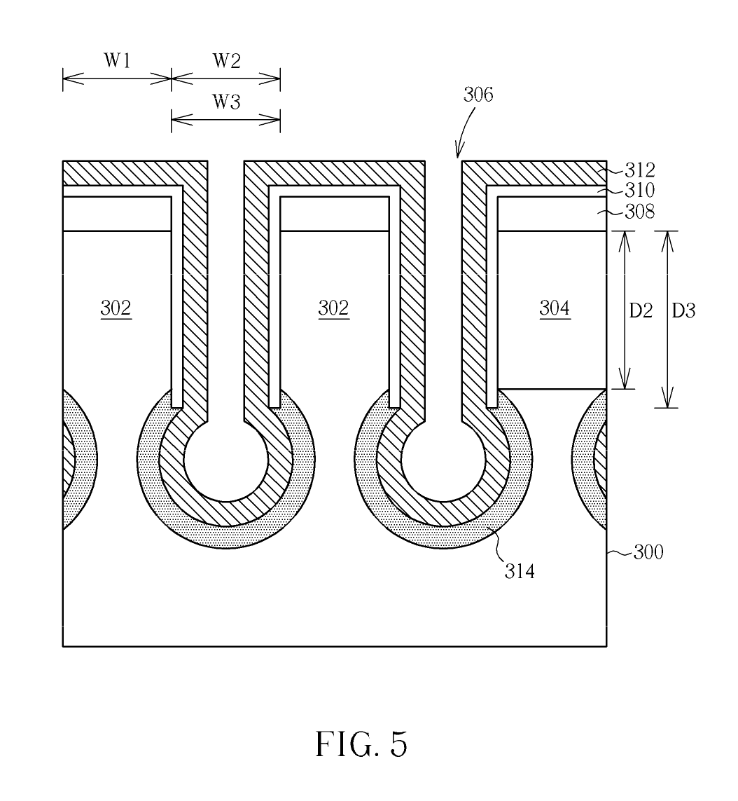

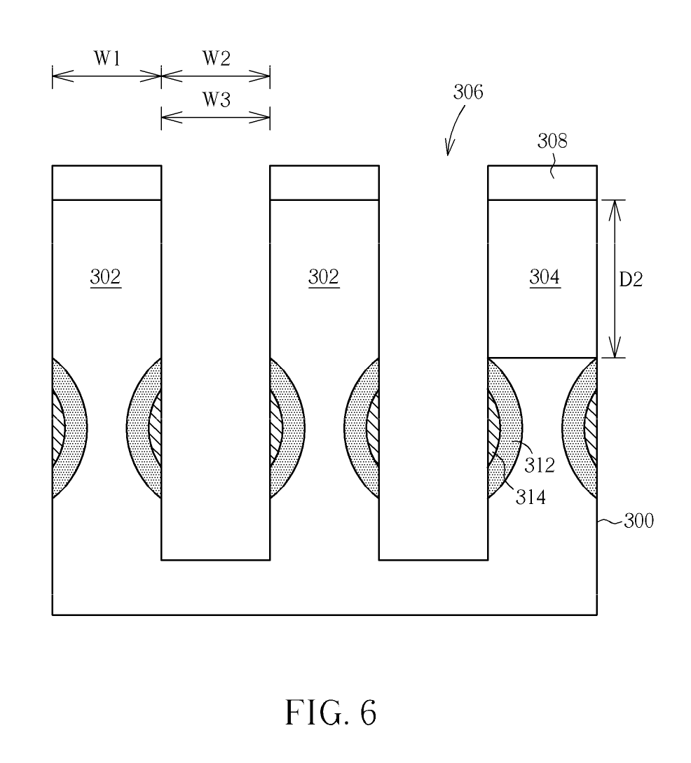

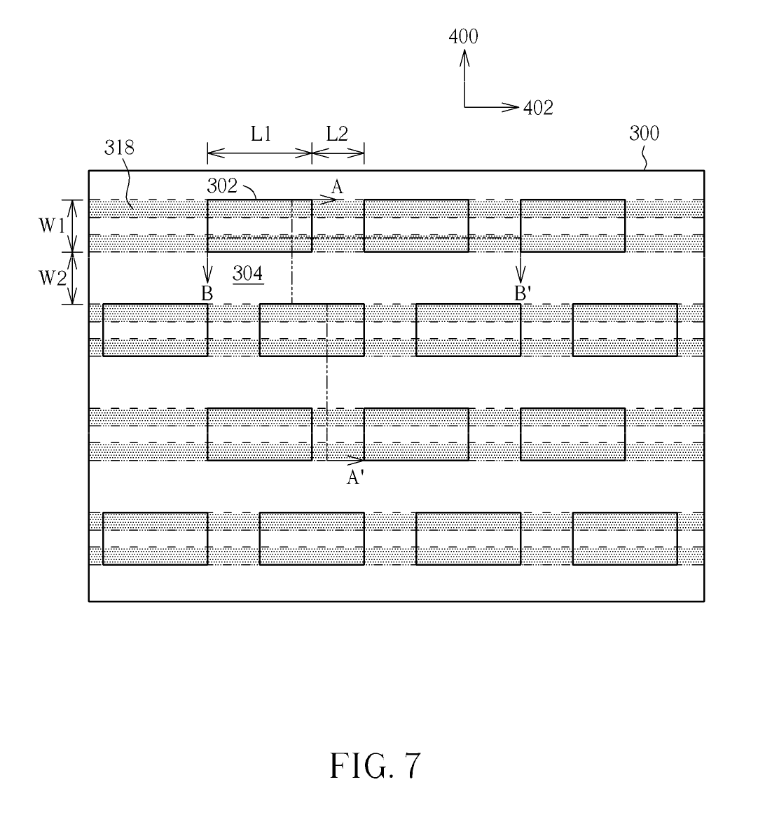

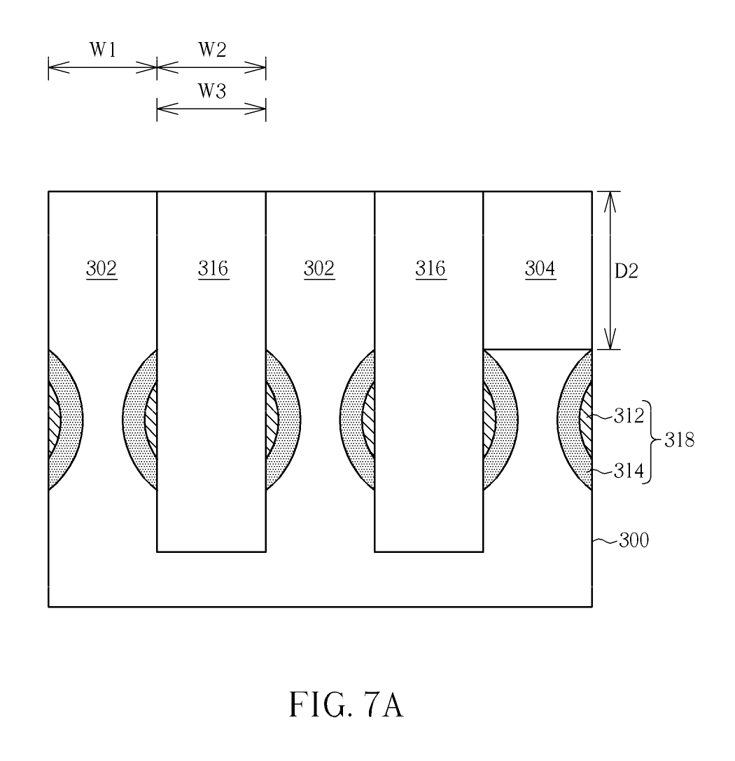

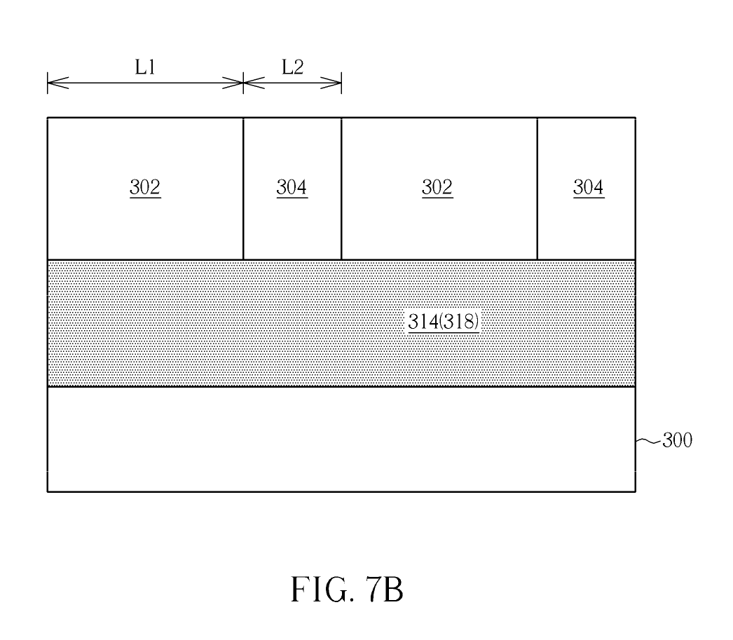

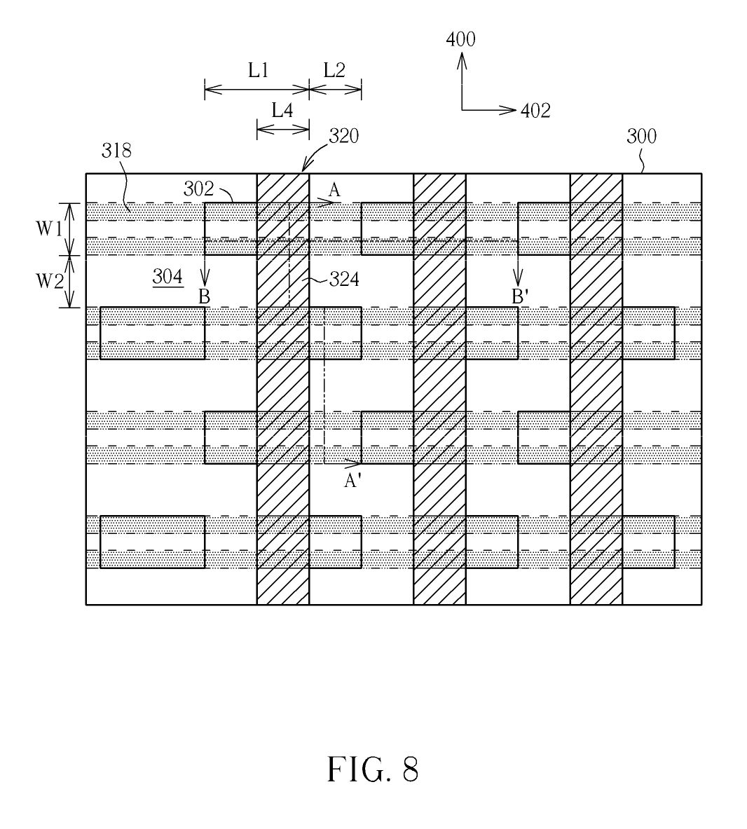

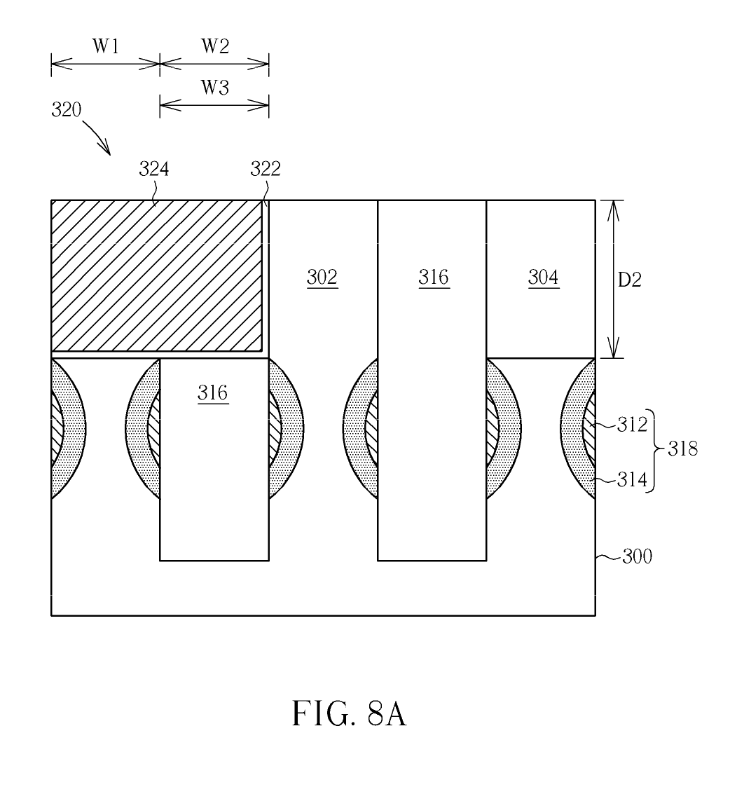

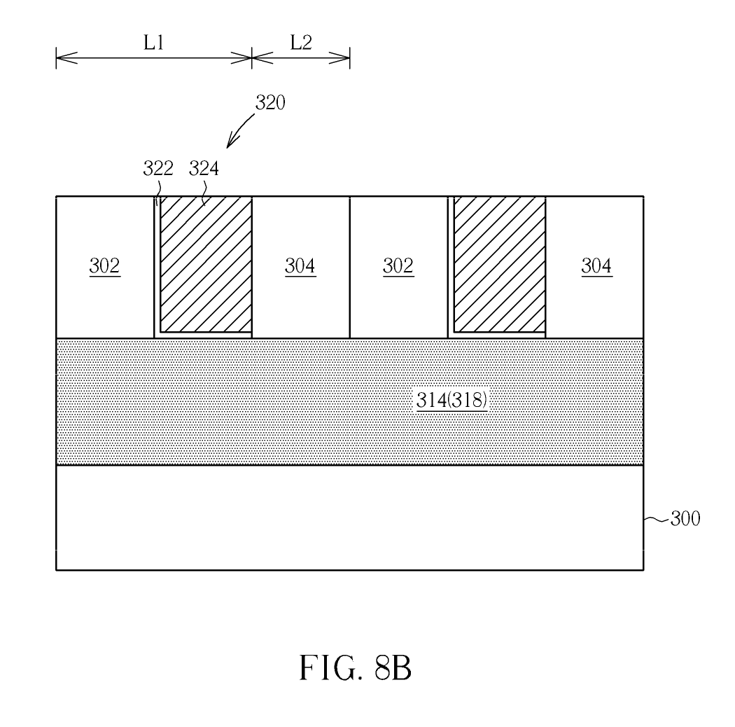

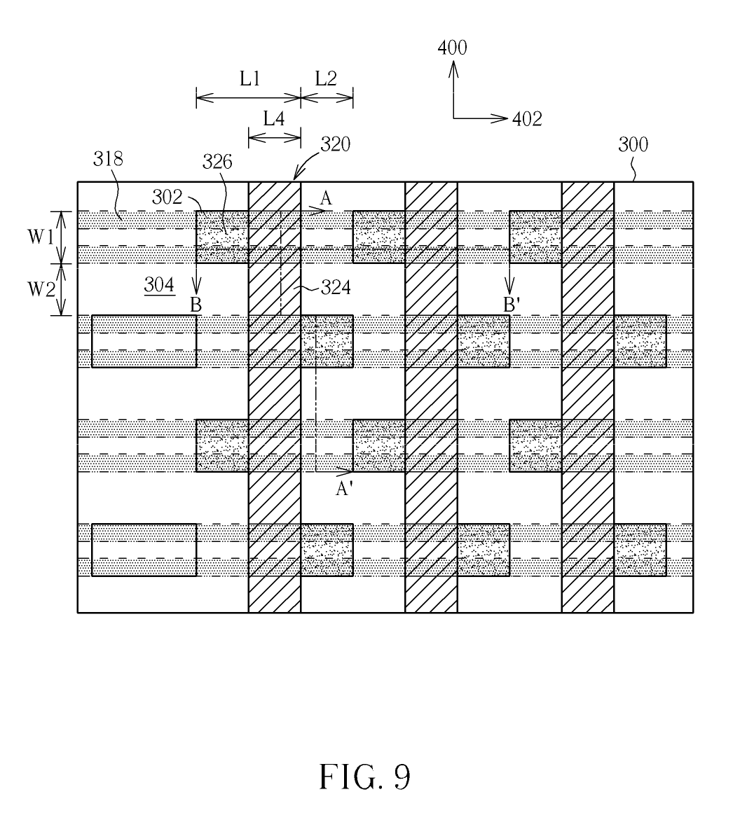

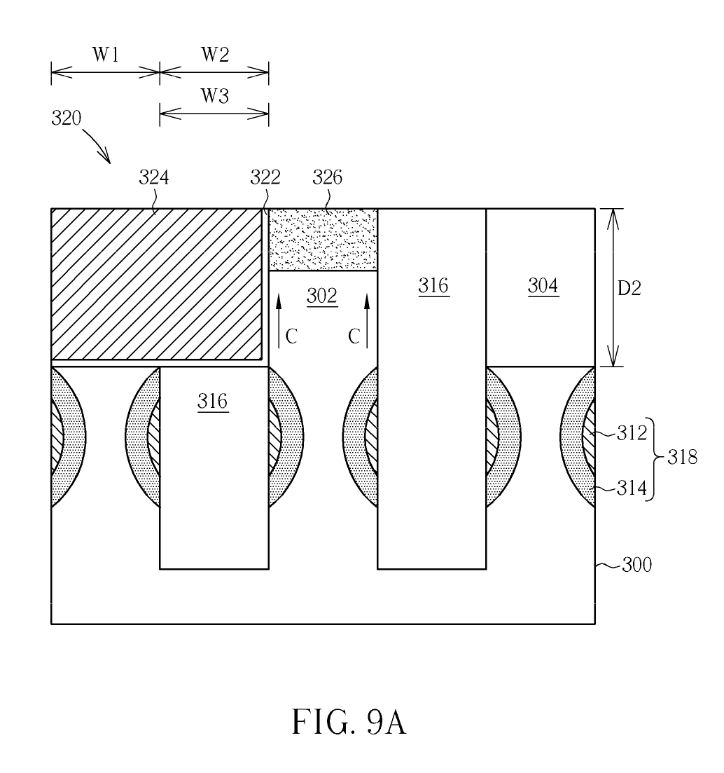

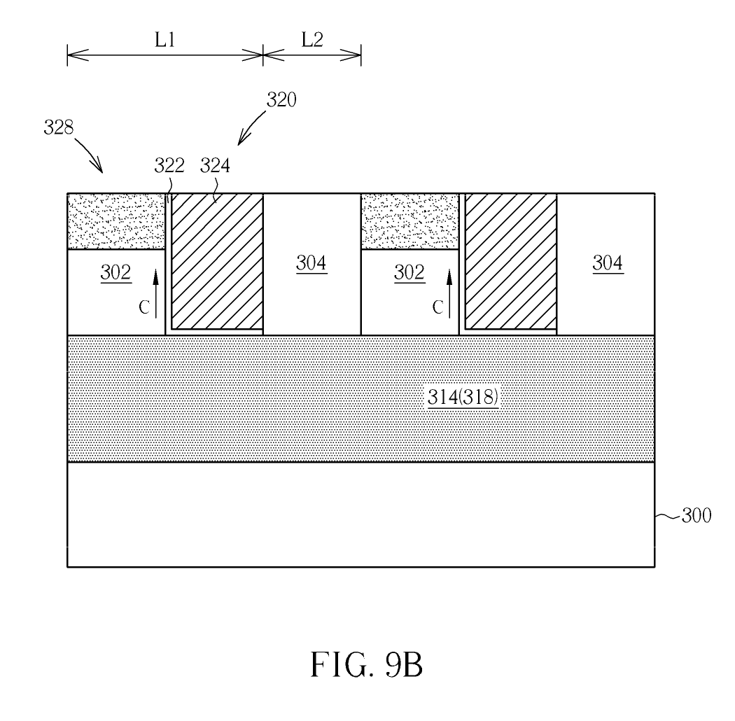

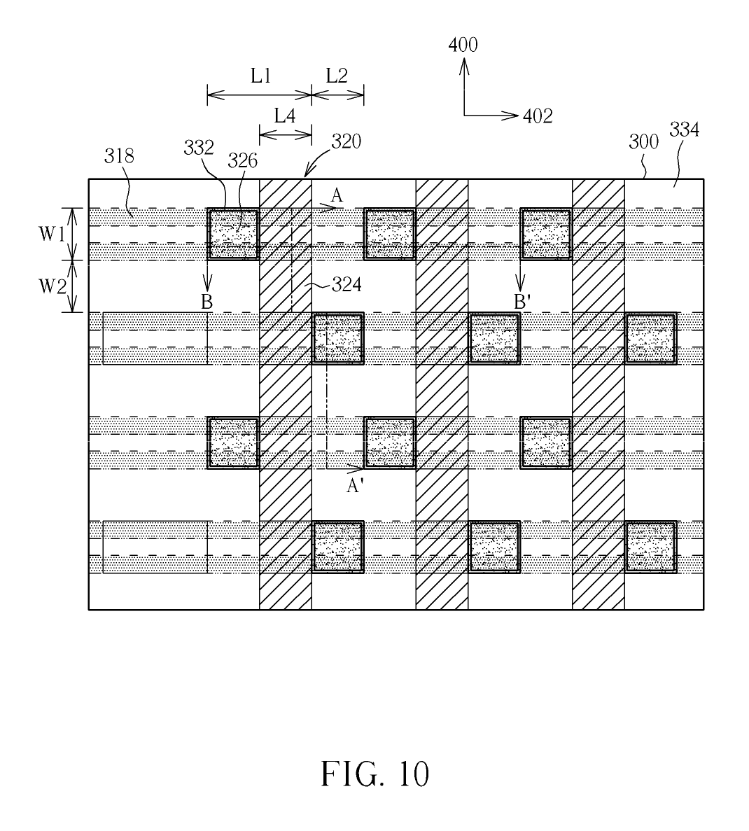

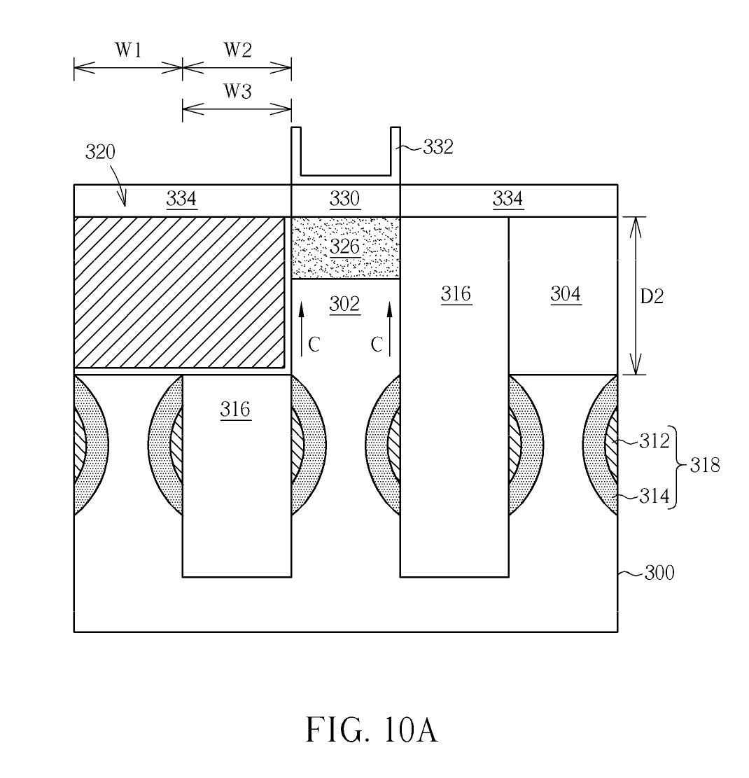

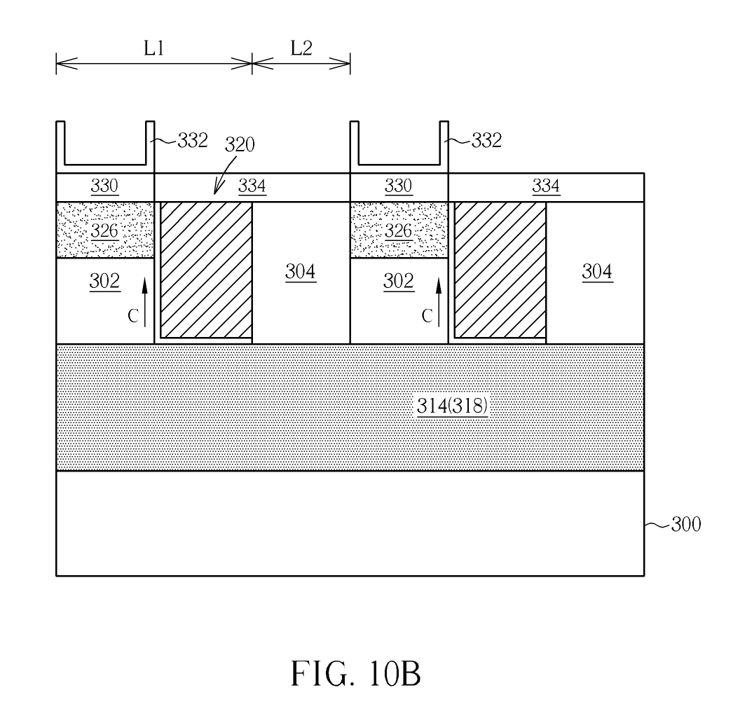

Please refer to FIG. 1, FIG. 1A, FIG. 1B, FIG. 2 to FIG. 6, FIG. 7, FIG. 7A, FIG. 7B, FIG. 8, FIG. 8A, FIG. 8B, FIG. 9, FIG. 9A, FIG. 9B, FIG. 10, FIG. 10A and FIG. 10B, which are schematic diagrams of a method of manufacturing the memory array provided in the present invention. FIG. 1A, FIG. 2 to FIG. 6, FIG. 7A, FIG. 8A, FIG. 9A and FIG. 10A show cross-sectional views along the AA′ line drawn in FIG. 1, FIG. 6, FIG. 7, FIG. 8, FIG. 9 and FIG. 10, respectively. FIG. 1B, FIG. 7B, FIG. 8B, FIG. 9B and FIG. 10B show cross-sectional views along the BB′ line drawn in FIG. 1, FIG. 6, FIG. 7, FIG. 8, FIG. 9 and FIG. 10, respectively.

As shown in FIG. 1, FIG. 1A and FIG. 1B, a substrate 300 is provided. The substrate 300 may be a silicon substrate, an epitaxial silicon substrate, a silicon germanium substrate, a silicon carbide substrate or a silicon-on-insulator (SOI) substrate, but is not limited thereof. An isolation region 304 is formed in the substrate 300 thereby defining a plurality of active regions 302, each of which is encompassed by the isolation region 304. In one present embodiment, the isolation region 304 is for example a shallow trench isolation (STI), which is made of SiO₂ or other suitable dielectric materials. The isolation region 304 has a depth D2 substantially between 500 micro meters (μm) and 1000 μm.

In one embodiment, each of the active regions 302 has a rectangular shape and is arranged in arrays. As shown in FIG. 1, in the first direction 400, the active regions 302 and the isolation region 304 are arranged alternatively, wherein a width W1 of the active region 302 is substantially equal to a width W2 of the isolation region 304. In the second direction 402, the active regions 302 and the isolation region 304 are arranged alternatively, wherein a length L1 of the active region 302 is substantially twice the length L2 of the isolation region 304. In one preferred embodiment, W1, W2 and L2 are equal to the critical dimension (CD) of the lithography apparatus applied for the semiconductor substrate 300, and L1 is about twice as the CD. That is, W1:W2:L1:L2=1:1:2:1. In addition, each of the active regions 302 extending along the second direction 402 (that is, disposed in the same row) has a shift with respect to the active regions 302 in the adjacent row, wherein the shift value is about ½ L1. In other words, the projection of the active regions 302 in one row will partially overlap with the active regions 302 in another row, and the length of the overlapping region is about ½ L1.

Please refer to FIG. 2 to FIG. 6, and also refer to FIG. 1. FIG. 2 to FIG. 6 are schematic diagrams of the method of forming buried bit lines in the present invention, wherein FIG. 2 to FIG. 6 are illustrations according to the line AA′ in FIG. 1. As shown in FIG. 2, a plurality of first trenches 306 extending along the second direction 402 is formed on the substrate 300. The first trenches 306 are formed within the isolation region 304 but are not formed in the active region 302. In one embodiment, the first trench 306 has a width W3, which is substantially equal to or smaller than the width W2, preferably equal to width W2. This way, the buried bit formed in the subsequent step can be located mainly below the active region 302. Besides, the first trench 306 has a depth D₃ which is substantially equal to or greater than the depth D2, preferably equal to the depth D2. The steps of forming the first trenches 306, for example, include forming a patterned hard mask layer 308. Then, an etching process is performed by using the patterned hard mask 308 as a mask to form the first trenches 306. The patterned hard mask 308, for instance, can be made of silicon nitride (SiN), silicon oxynitride (SiON), silicon carbide (SiC) or the combination thereof. Then, a liner 310 is formed on the substrate 300 and the sidewalls of the first trench 306. Preferably, the liner 310 is not formed on the bottom surface of the first trench 306, and in another embodiment, the liner 310 can be formed on a part of the bottom surface of the first trench 306 and exposes a part of the bottom surface. In one embodiment, the liner 306 may be made of oxide such as aluminum oxide (Al₂O₃) which can be formed by an atomic layer deposition (ALD) process.

As shown in FIG. 3, an isotropic etching process, such as a wet etching step, is performed to widen the bottom surface of the first trench 306 so that the bottom surface of the first trench 306 becomes a curved bottom surface with a nearly round shape in the cross-section. The wet etching step can, for example, use hydrogen fluoride (HF). Thanks to the protection of the liner 310, the sidewalls of the first trench 306 are not etched away.

As shown in FIG. 4, a material layer 312 is formed on the substrate 300. The material layer 312 is formed along the surface of the first trench 306 to cover at least the curved bottom surface of the first trench. In one embodiment, the first trench 306 is not completely filled with the material layer 312. In another embodiment, the first trench 306 is completely filled with the material layer 312. The material layer 312, for example, can include poly-silicon, but is not limited thereto.

Next, as shown in FIG. 5, an annealing process is performed to diffuse the dopants of the material layer 312 into the substrate 300, thereby forming a doping area 314 in the vicinity of the curved bottom surface of the first trench 306. The doping area 314 will become the source region of the vertical transistor. It is understood that the doping area 314 would diffuse into the substrate 300 in the active region 302 and have a shape of semi-circle, or segment of circle, but is not limited thereto. To one of ordinary skill in the art, the doping area 314 may have other shapes by adjusting the parameters of the annealing process or the deposition process.

As shown in FIG. 6, a dry etching process is performed by using the patterned hard mask 308 as a mask to remove the liner 310 and the material layer 312 in the first trench region 306. In one embodiment, the etching process would deepen the depth of the first trench 306 by further removing the substrate 300 under the curved bottom surface.

As shown in FIG. 7, 7A and 7B, an insulation layer 316 such as silicon oxide is filled into the first trench 306. Then, the patterned hard mask 306 is removed so that the substrate 300 in the active region 302 is leveled with the insulation layer 316. It is worth noting that the material layer 312 and the doping area 314 are located on two sides of the insulation region 316 and below the active region 302. Therefore, the material layer 312 and the doping area 314 together become a buried line 317. In one embodiment, since the insulation layer 316 and the isolation region 304 are made of silicon oxide for example, the insulation layer 316 can also provide electrical insulation function and serve as a part of the isolation region 304.

As shown in FIG. 8, FIG. 8A and FIG. 8B, a plurality of second trenches 320 extending along the first direction 400 is formed on the substrate 300. The second trench 320 would be formed at least on the overlapping region of the active region 302 in each row. In one embodiment, the second trench 320 has a length L₄ substantially equal to ½ L1 and has a depth D₄ substantially equal to D2 and D₃. In another embodiment, L₄ can be greater than ½ L1 and D₄ can be smaller than D₃. Then, a gate dielectric layer 322 is formed on the button surface and the sidewalls of the second trench 320. The gate dielectric layer 322 can be composed of silicon oxide or high-k dielectric material, which includes, for example, hafnium oxide (HfO₂), hafnium silicon oxide (HfSiO₄), hafnium silicon oxynitride (HfSiON), aluminum oxide (Al₂O3), lanthanum oxide (La₂O₃), lanthanum aluminum oxide (LaAlO), tantalum oxide (Ta₂O₅), zirconium oxide (ZrO₂), zirconium silicon oxide (ZrSiO₄), hafnium zirconium oxide (HfZrO), yttrium oxide (Yb₂O₃), yttrium silicon oxide (YbSiO), zirconium aluminate (ZrAlO), hafnium aluminate (HfAlO), aluminum nitride (MN), titanium oxide (TiO₂), zirconium oxynitride (ZrON), hafnium oxynitride (HfON), zirconium silicon oxynitride (ZrSiON), hafnium silicon oxynitride (HfSiON), strontium bismuth tantalite (SrBi₂Ta₂O₉, SBT), lead zirconate titanate (PbZrₓTi₁₋ₓI₃, PZT) or barium strontium titanate (BaₓSr₁₋ₓTiO₃, BST), but is not limited thereto. Then, a gate layer is formed on the gate dielectric layer 322 to fill the second trench 320, thereby forming a plurality of word lines 324. The gate layer preferably includes low-resistance materials, for example, poly-silicon or metals such as Au, Ag, Cu, Al, Mo, Ti, Ta, Cd, but is not limited thereto.

As shown in FIG. 9, FIG. 9A and FIG. 9B, an ion implant process is carried out on the areas in the active region 30 not covered by the word line 324, thereby forming a plurality of drain regions 326. A storage transistor 328 of the memory array in the present invention is therefore formed. The storage transistor 328 has a vertical channel C. Then, as shown in FIG. 10, a plurality of capacitors 332 are formed above the substrate 300 and are electrically connected to the drain regions 326. For example, a dielectric layer 334 can be formed on the substrate 300 and a plurality of storage node contacts (also called landing pads) 330 is formed in the dielectric layer 334 above the drain region 326 of the storage transistor 328 correspondingly. Finally, a plurality of capacitors 332 is formed and electrically connected to the storage node contacts 330. The capacitors 332 can be any types of capacitor, such as capacitors with crown electrode.

As shown in FIG. 10, FIG. 10A and FIG. 10B, the present invention further provides a memory array 336. A first direction 400 and a second direction 402, which are perpendicular to each other, are defined on the memory array 336. The memory array 336 includes a substrate 300, an isolation region 304, a plurality of active regions 306, a plurality of buried bit lines 318, a plurality of word lines 324, a plurality of drain regions 326 and a plurality of capacitors 332. The isolation region 304 and the active regions 302 are disposed in the substrate 300, and each of the active regions 302 is separated and encompassed by the isolation region 304. In one embodiment of the present invention, the active region 302 and the isolation region 304 are arranged alternatively along the first direction 400. The active region 302 has a width W1 and the isolation region 304 has width W2 along the first direction 400. The width W1 is substantially equal to the width W2. W1 and W2 are preferably equal to the critical dimension (CD) of the lithography apparatus used for the semiconductor substrate 300. In another embodiment, the active region 302 and the isolation region 304 are arranged alternatively in the second direction 402. The active region 302 has a length L1 and the isolation region 304 has a length L2 along the second direction 402. The length L1 is substantially twice the length L2, and preferably, L2 is equal to the critical dimension of the lithography apparatus used for the semiconductor substrate 300. In addition, each of the active regions 302 extending along the second direction 402 (that is, in the same row) has a shift with respect to the active regions 302 in the adjacent row, wherein the shift value is equal to the critical dimension.

The buried bit lines 318 are disposed in the substrate 300 and extend along the second direction 402. In one preferred embodiment, the buried bit lines 402 include a dopant source region 314 and a poly-silicon layer 312. In another embodiment, at least a part of the buried bit line 402 is disposed within the active region 302, wherein the side of the buried bit line 402 facing the active region 302 has a curved surface, so that the buried bit line 402 has a semi-circle or a segment of circle in its cross section. The word line 324 is disposed in the substrate 300 and extends along the first direction 400. A gate dielectric layer 322 is disposed between the word line 324 and the substrate 300. The drain region 326 is disposed in the active region 302 not covered by the word line 324. The capacitor 332 is disposed on the substrate 300 and is electrically connected to the drain region 326. In addition, according to the manufacturing method provided in the present invention (refer to FIG. 2 to FIG. 6), the depth of the isolation region (that is, the insulation layer 316) between each buried bit line 318 is substantially greater than that in other regions, which means in the regions between the drain regions 326 and the adjacent word lines 324 (please refer to the right part of FIG. 10A).

In light of above, the present invention provides a memory array and the manufacturing method thereof. The novel arrangement of the active regions and the isolation region is one salient feature of the present invention. The vertical transistors and the buried bit lines are formed on the substrate according to the arrangement so the integrity thereof can be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a memory array, comprising:
providing a substrate wherein a first direction and a second direction which are substantially perpendicular to each other are defined on the substrate;
forming an isolation region in the substrate to define a plurality of active regions encompassed by the isolation region;
after forming the isolation region, forming a plurality of buried bit lines in the substrate extending along the second direction;
forming a plurality of word lines in the substrate extending along the first direction and a gate dielectric layer disposed between the substrate and the word line;
forming a plurality of drain regions in the active regions not covered by the word line; and
forming a plurality of capacitors on the substrate to electrically connect each drain region.

2. The manufacturing method of a memory array according to claim 1, wherein the active regions and the isolation region are arranged alternatively along the first direction, wherein the active region has a width W1 and the isolation region has width W2 along the first direction.

3. The manufacturing method of a memory array according to claim 2, wherein the width W1 is substantially equal to the width W2.

4. The manufacturing method of a memory array according to claim 2, wherein the width W1 and the width W2 are substantially equal to the critical dimension of the lithography apparatus used for the substrate.

5. The manufacturing method of a memory array according to claim 1, wherein the active regions and the isolation region are arranged alternatively along the second direction wherein the active region has a length L1 and the isolation region has a length L2 along the second direction.

6. The manufacturing method of a memory array according to claim 5, wherein the length L1 is substantially twice as the length L2.

7. The manufacturing method of a memory array according to claim 5, wherein the length L2 is substantially equal to the critical dimension of the lithography apparatus used for the substrate, and the length L1 is substantially twice the critical dimension of the lithography apparatus used for the substrate.

8. The manufacturing method of a memory array according to claim 1, wherein each of the active regions in the same row has a shift with respect to the active regions in the adjacent row.

9. The manufacturing method of a memory array according to claim 8, wherein the shift is substantially equal to the critical dimension of the lithography apparatus applied for the substrate.

10. The manufacturing method of a memory array according to claim 1, wherein the step of forming the buried bit lines comprises:
forming a plurality of first trenches in the substrate, wherein the first trench has sidewalls and a bottom surface;
forming a line on the sidewalls of the first trench;
enlarging the bottom surface of the first trench so that the bottom surface has a curved surface;
forming a doping area in the substrate adjacent to curved bottom surface;
deepening the first trench; and
filling an insulation layer into the first trench.

11. A memory array, comprising:
a substrate, wherein a first direction and a second direction which are perpendicular to each other are defined on the substrate;
an isolation region and a plurality of active regions disposed in the substrate, wherein the active regions are isolated with each and encompassed by the isolation region, and the active regions in the same row has a shift with respect to the active regions in the adjacent row;
a plurality of buried bit lines disposed in the substrate; wherein the buried bit lines extend along the second direction;
a plurality of word lines disposed in the substrate, wherein the word lines extend along the first direction;
a plurality of drain regions disposed on the active regions not covered by the word lines; and
a plurality of capacitors disposed on the substrate and electrically connected to the drain regions.

12. The memory array according to claim 11, wherein the active regions and the isolation region are arranged alternatively along the first direction wherein the active region has a width W1 and the isolation region has width W2 along the first direction.

13. The memory array according to claim 12, wherein the width W1 is substantially equal to the width W2.

14. The memory array according to claim 12, wherein the width W1 and the width W2 are substantially equal to the critical dimension of the lithography apparatus used for the substrate.

15. The memory array according to claim ii, wherein the active regions and the isolation region are arranged alternatively along the second direction wherein the active region has a length L1 and the isolation region has a length L2 along the second direction.

16. The memory array according to claim 15, wherein the length L1 is substantially twice the length L2.

17. The memory array according to claim 15, wherein the length L2 is substantially equal to the critical dimension of the lithography apparatus used for the substrate, and the length L1 is substantially twice as the critical dimension of the lithography apparatus used for the substrate.

18. The memory array according to claim 11, wherein the shift is substantially equal to the critical dimension of the lithography apparatus used for the substrate.

19. The memory array according to claim 11, wherein the buried bit line comprises a poly-silicon layer and a source region.

20. The memory array according to claim 11, wherein the depth of the isolation region between each buried bit line is substantially greater than that of the isolation region between the drain region and the adjacent word line.
